(19) United States
(12) Patent Application Publication
(10) Pub. No.: US 2006/0245848 A1
(43) Pub. Date: Nov. 2, 2006

(54) Substrate cassette

(75) Inventor: Chin-Li Wang, Kaohsiung County (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Allied Material Technology Corporation

(21) Appl. No.: 11/121,664

(22) Filed: May 4, 2005

(30) Foreign Application Priority Data
Mar. 18, 2005 (TW) 094108377

(51) Int. Cl. H01L 21/677

(52) U.S. Cl. 414/217

(57) ABSTRACT

A substrate cassette includes a top frame, a bottom frame, a plurality of side plates and a plurality of supporting units. The side plates are used to connect the top frame and the bottom frame. Each supporting unit includes a plurality of connection rods, a plurality of supporting rods and substrate-supporting rods. Each connection rod is used to connect two neighboring side plates. The supporting rods are connected between corresponding connection rods, and the substrate-supporting rods are positioned on the supporting rods to support substrates.

### BACKGROUND OF THE INVENTION

1. Field of the Invention

The present invention relates to a substrate cassette, and in particular to a substrate cassette which is used to support plate-like substrate.

2. Description of Related Art

Because flat panels or liquid crystal display (LCD) panels have high contrast ratio and low power consumption and are light and thin, the LCD panels have been widely used in computer consumer products. Presently, active matrix thin-film transistor (TFT) LCD panels are dominating production among these flat panels. A glass substrate is a main component of the LCD panel, and a substrate cassette typically is needed to protect and transport the glass substrate when manufacturing of LCD panel is underway.

Reference is made to FIG. 1. FIG. 1 is illustrating a substrate cassette in the prior art. A substrate cassette 100a is made of resin and has a box-like structure. A plurality of sets of corresponding protrusions 101a are positioned on inner surfaces of the substrate cassette. A substrate 102a is transported and placed on the corresponding protrusions 101a by a handling device, e.g. a robot (not shown). Thickness of one glass substrate is about 0.7 mm. When the substrate 102a is placed on the corresponding protrusions 101a of the substrate cassette 100a, only the edges of the substrate 102a are supported by the corresponding protrusions 101a. However, due to gravitational force, the substrate 102 is bent and the extent of bending at the central portion of the substrate 102 can be significant.

Reference is made to FIG. 2. FIG. 2 illustrates another kind of substrate cassette in the prior art. As shown in FIG. 2, a substrate cassette 200a is also made of resin and has a box-like structure. A plurality of sets of corresponding protrusions 201a are positioned on inner surfaces of the substrate cassette. To overcome bending of the substrate 200a due to gravitational force, a plurality of supporting bars 203a are positioned on the inner surface of the backside of substrate cassette and extend toward the front side thereof. A substrate 202a is transported and placed on the corresponding protrusions 201a by a robot (not shown). Unlike the substrate cassette of FIG. 1, the substrate 202a is supported by both corresponding protrusions 201a and supporting bars 203a so that the extent of bending of the substrate is decreased. However, the size of a typical glass substrate is getting larger and larger so that the bending of the glass substrate cannot be effectively solved. For example, the size of G6 glass substrate is about 1500 mm×1800 mm. Thus, as shown in FIGS. 1 and 2, the gap between neighboring substrates can become too small because the substrates can be significantly bent. Thus, it is likely for the substrates to be broken when the handling device accesses the substrates.

Furthermore, if the handling device fails to access the substrates, then the distance between neighboring protrusions needs to be increased. However, the volume of a substrate cassette with an enlarged distance between neighboring protrusions is too large to be transported and handled. And, cost of handling this cassette is also increased.

### BRIEF SUMMARY OF THE INVENTION

The present invention provides a substrate cassette. An embodiment of a substrate cassette includes a top frame, a bottom frame, a plurality of side plates and a plurality of supporting units. The side plates are used to movably connect with both the top frame and the bottom frame. Each supporting unit includes a plurality of connection rods, a plurality of supporting rods and substrate-supporting rods. Each connection rod is used to movably connect two neighboring side plates. The supporting rods are movably connected between corresponding connection rods, and the substrate-supporting rods are movably positioned on the supporting rods to support substrates. A gap located between the substrate and supporting rods is sized to accommodate a handling device.

### BRIEF DESCRIPTION OF THE DRAWINGS

The present invention can be fully understood from the following detailed description and preferred embodiment with reference to the accompanying drawings, in which:

FIG. 1 is illustrating a substrate cassette in the prior art;

FIG. 2 is illustrating another substrate cassette in the prior art;

FIG. 3 is a perspective view of the first embodiment of a substrate cassette according to the present invention;

FIG. 4 is a front elevational view of the substrate cassette of FIG. 3;

FIG. 5 is a front elevational view of the second embodiment of a substrate cassette according to the present invention;

FIG. 6 is an enlarged drawing taken along the dash-line of the substrate cassette of FIG. 5; and

FIG. 7 is a front elevational view of the third embodiment of a substrate cassette of the present invention.

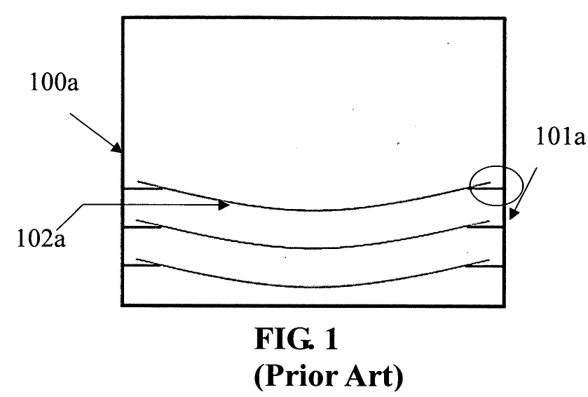

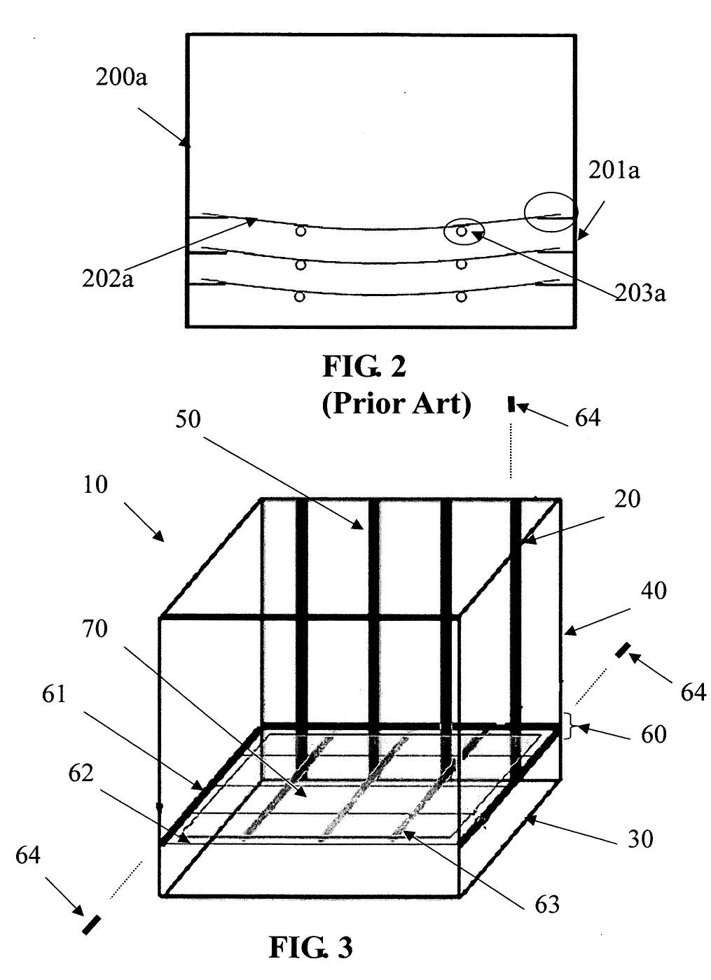

### DETAILED DESCRIPTION OF THE INVENTION

The following detailed description is of the best presently contemplated modes of carrying out the invention. This description is not to be taken in a limiting sense, but is made merely for the purpose of illustrating general principles of embodiments of the invention. The scope of the invention is best defined by the appended claims.

Reference is made to FIG. 3. FIG. 3 is a perspective view of the first embodiment of a substrate cassette according to the present invention. As shown in FIG. 3, a substrate cassette 10 includes a top frame 20, a bottom frame 30, a plurality of side plates 40, a plurality of backside plates 50 and a plurality of supporting units 60. The top frame 20 is positioned opposite to the bottom frame 30. The side plates 40 are used to connect the top frame 20 and the bottom frame 30. The backside plates 50 are movably connected between the top frame 20 and the bottom frame 30 to prevent the substrate from slipping out of the substrate cassette 10. In addition, each supporting unit 60 includes a plurality of connection rods 61, a plurality of supporting rods 62 and a plurality substrate-supporting rods 63.

Reference is further made to FIG. 3. As shown in FIG. 3, each connection rod 61 is used to connect two neighboring side plates 40. The supporting rods 62 are connected between corresponding connection rods 61, and the substrate-supporting rods 63 are movably positioned at the supporting rods 62. The connection rod 61 can be secured between two neighboring side plates 40 by screws 64, and the supporting rods 62 can be connected between corresponding connection rods 61 by screws 64. The number of the supporting rods 62 can be increased or decreased if necessary. The substrate-supporting rods 63 can be made of Polyphenylene Sulfide (PPS), Polyetheretherketone (PEEK), Polyphthalamide (PPA), Polyetherketoneketone (PEKK) or Thermoplastic Polyimide (TPI).

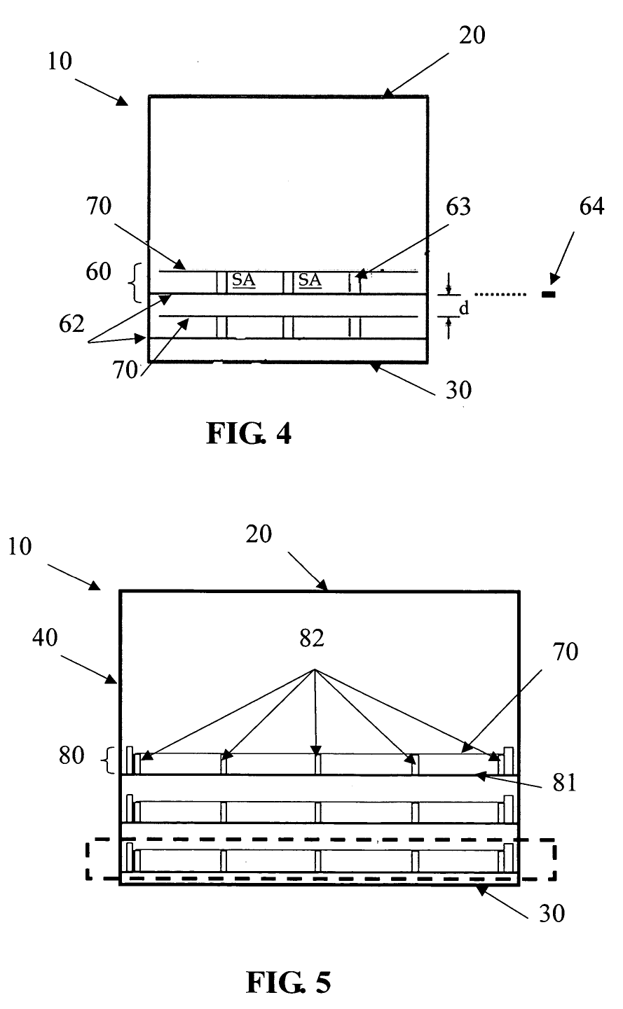

Reference is made to FIG. 4. FIG. 4 shows a front elevational view of the substrate cassette of FIG. 3. There are two substrates 70 in the substrate cassette 10, and the substrates 70 are positioned on the supporting unit 60. Spaces SA are formed between the substrate 70 and the supporting rods 62 because of presence of substrate-supporting rods 63. Thus, the spaces SA are sized to accommodate the handling device (not shown) to access one of the substrates 70 of the substrate cassette 10 when the handling device is accessing the substrate 70. Bending of the substrates 70 is reduced so the handling device does not break the substrate 70. The distance d between the supporting rods 62 and the substrate 70 is adjustable if necessary. Thus, the substrate cassette 10 can accommodate more substrates than conventional substrate cassettes and does not result in the substrates 70 being broken because of the shorter the distance d.

Reference is made to FIG. 5. FIG. 5 illustrates a front elevational view of the second embodiment of a substrate cassette of the present invention. As shown in FIG. 5, the second embodiment of the present invention includes the top frame 20, the bottom frame 30 and a plurality of side plates 40. FIG. 5 illustrates the substrate cassette 10 having a plurality of supporting unit 80. Each supporting unit 80 of substrate cassette 10 is used to support the substrates 70 with the same size and has a supporting plate 81 that is movably connected with corresponding side plates 40. Also, a plurality of substrate-supporting rods 82 are movably positioned at the supporting plate 81 and used to support the substrates 70. Some of the substrate-supporting rods 82 include guide ramps 83 used to guide the substrate. The substrate-supporting rods 82 can be made of Polyphenylene Sulfide (PPS), Polyetheretherketone (PEEK), Polyphthalamide (PPA), Polyetherketoneketone (PEKK) or Thermoplastic Polyimide (TPI).

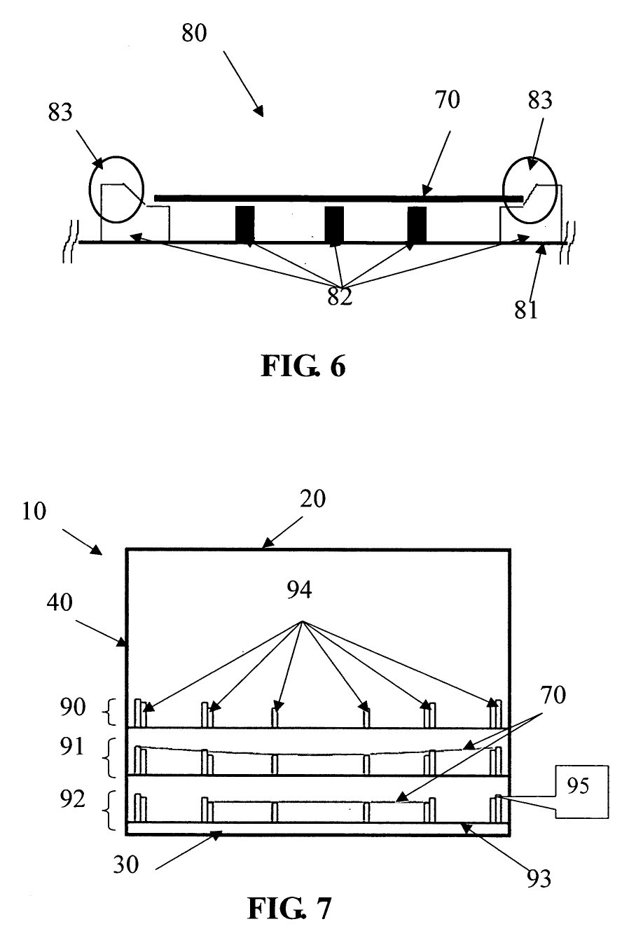

Reference is made to FIG. 6. FIG. 6 shows an enlarged drawing of one supporting unit 80. As shown in FIG. 6, there is an inclined plane in the guide ramp 83 of the substrate-supporting rod 82. When the substrate 70 is positioned at the supporting unit 80 by the handling device (not shown), the substrate 70 slides downwardly along the inclined surfaces of the guide ramps 83 and is supported by the top surfaces of all of the substrate-supporting rods 82. Thus, it is possible to prevent the substrate 70 from being broken even though the substrate 70 is not accurately placed on the supporting unit 80.

Reference is made to FIG. 7. FIG. 7 illustrates the third embodiment of a substrate cassette according to the present invention. Like the previous embodiments, the third embodiment of the present invention also includes the top frame 20, the bottom frame 30 and a plurality of side plates 40. As shown in FIG. 7, the substrate cassette 10 has a plurality of supporting units 90, 91 and 92. The supporting units 90, 91 and 92 of substrate cassette 10 are respectively used to support the substrates 70 with the different sizes and have corresponding supporting plates 93. The supporting plates 93 are movably connected with corresponding side plates 40. A plurality of substrate-supporting rods 94 are movably positioned at the supporting plate 93 and used to support the substrates 70. Some of the substrate-supporting rods 94 include guide ramps 95 used to guide the substrate 70. The substrate-supporting rods 94 can be made of Polyphenylene Sulfide (PPS), Polyetheretherketone (PEEK), Polyphthalamide (PPA), Polyetherketoneketone (PEKK) or Thermoplastic Polyimide (TPI).

While the invention has been described with reference to the preferred embodiments, the description is not intended to be construed in a limiting sense. It is therefore contemplated that the appended claims will cover any such modifications or embodiments as may fall within the scope of the invention defined by the following claims and their equivalents.

What is claimed is:

1. A substrate cassette for supporting glass substrates, comprising:
a top frame;
a bottom frame, positioned opposite to the top frame;
a plurality of side plates, movably connecting with both the top frame and the bottom frame such that the glass substrates are prevented from slipping out of the substrate cassette; and
a plurality of supporting units, wherein each supporting unit is configured to support a glass substrate and comprises:
a plurality of connection rods, movably connecting between two neighboring side plates;
a plurality of supporting rods, being movably connected between corresponding connection rods; and
substrate-supporting rods, being movably positioned on the supporting rods to support the glass substrates such that spaces are formed between the glass substrate and the supporting rods.

2. The substrate cassette as claimed in claim 1, further comprising a plurality of backside plates being movably connected between the top frame and the bottom frame to prevent a substrate supported by one of the supporting units from sliding out of the one of the supporting units.

3. The substrate cassette as claimed in claim 1, wherein the substrate-supporting rods are made of Polyphenylene Sulfide (PPS), Polyetheretherketone (PEEK), Polyphthalamide (PPA), Polyetherketoneketone (PEKK) or Thermoplastic Polyimide (TPI).

4. The substrate cassette as claimed in claim 1, wherein the supporting units are integrally formed with the side plates.

5. The substrate cassette as claimed in claim 1, wherein the supporting unit are connected between the side plated by screws.

6. The substrate cassette as claimed in claim 2, wherein the backside plates are connected with the top frame and the bottom frame by screws.

7. The substrate cassette as claimed in claim 1, wherein each supporting unit has substrate-supporting rods with different heights and is used to support the substrates of different sizes.

8. The substrate cassette as claimed in claim 1, wherein the substrate-supporting rods are integrally formed with the supporting rods.

9. A substrate cassette, comprising:
a top frame;
a bottom frame, positioned opposite to the top frame;
a plurality of side plates, movably connecting with both the top frame and the bottom frame such that glass substrates are prevented from slipping out of the substrate cassette;
a plurality of supporting units, wherein each supporting unit is configured to support a glass substrate and comprises:
a plurality of connection rods, movably connecting between two neighboring side plates;
a plurality of supporting rods, being movably connected between corresponding connection rods; and
substrate-supporting rods, being movably positioned on the supporting rods to support the glass substrates such that spaces are formed between the glass substrate and the supporting rods,
a plurality of backside plates being movably connected between the top frame and the bottom frame to prevent one of the glass substrates supported by one of the supporting units from sliding out of the one of the supporting units.

10. The substrate cassette as claimed in claim 9, wherein the substrate-supporting rods are made of Polyphenylene Sulfide (PPS), Polyetheretherketone (PEEK), Polyphthalamide (PPA), Polyetherketoneketone (PEKK) or Thermoplastic Polyimide (TPI).

11. The substrate cassette as claimed in claim 9, wherein the top frame and the bottom frame are made of resin.

12. The substrate cassette as claimed in claim 9, wherein the supporting units are integrally formed with the side plates.

13. The substrate cassette as claimed in claim 9, wherein each supporting unit has substrate-supporting rods with different heights and is used to support the substrates of different sizes.

14. The substrate cassette as claimed in claim 9, wherein the backside plates are connected with the top frame and the bottom frame by screws.

15. A substrate cassette, comprising:
a top frame;
a bottom frame, positioned opposite to the top frame;
a plurality of side plates, movably connecting with both the top frame and the bottom frame such that glass substrates are prevented from slipping out of the substrate cassette;
a plurality of supporting units, wherein each supporting unit comprising:
a plurality of supporting plate, being movably connected with corresponding side plates; and
a plurality of substrate-supporting rods, being movably positioned on the supporting rods to support the glass substrates, and some of the substrate-supporting rods including guide ramps that are used to guide one of the glass substrates.

16. The substrate cassette as claimed in claim 15, wherein substrate-supporting rods are movably positioned on the supporting plates and have different heights.

17. The substrate cassette as claimed in claim 15, wherein the guide ramps of the substrate-supporting rods have inclined surfaces configured to contact a substrate placed on the substrate-supporting rods so that the substrate slides downwardly along the inclined surfaces of the guide ramps.

18. The substrate cassette as claimed in claim 15, wherein each supporting unit has substrate-supporting rods of different heights and is used to support the substrates of different sizes.
